(19) United States
(12) Patent Application Publication
(10) Pub. No.: US 2025/0120009 A1
(43) Pub. Date: Apr. 10, 2025

(54) SEMICONDUCTOR PACKAGE

(71) Applicant: Samsung Electronics Co., Ltd., Suwon-si (KR)

(72) Inventors: Dongwoo KIM, Suwon-si (KR); Seyeong SEOK, Suwon-si (KR); Daseul LEE, Suwon-si (KR); Jonghyeon CHANG, Suwon-si (KR)

(73) Assignee: Samsung Electronics Co., Ltd., Suwon-si (KR)

(21) Appl. No.: 18/825,308

(22) Filed: Sep. 5, 2024

(30) Foreign Application Priority Data
Oct. 5, 2023 (KR) 10-2023-0132597

(51) Int. Cl. H05K 1/02; H01L 23/00; H05K 1/11; H05K 1/18

(52) U.S. Cl. CPC H05K 1/0271; H05K 1/111; H05K 1/181; H01L 24/16; H01L 24/32; H01L 24/73; H01L 2224/16227; H01L 2224/32225; H01L 2224/73204; H01L 2924/15311; H05K 2201/09409; H05K 2201/09472; H05K 2201/10674; H05K 2201/10734; H05K 2201/10977

(57) ABSTRACT

A semiconductor package includes a base substrate including a lower surface; a semiconductor chip on the base substrate; and a plurality of connection bumps on the lower surface of the base substrate, wherein the plurality of connection bumps includes a first group including connection bumps arranged on the lower surface in a first direction, and a second group including connection bumps arranged on the lower surface in a second direction, the second direction having a first angle with respect to the first direction, the connection bumps of the first group are offset from each other in the first direction, and the connection bumps of the second group are offset from each other in the second direction.

### CROSS-REFERENCE TO RELATED APPLICATION(S)

This application claims benefit of priority to Korean Patent Application No. 10-2023-0132597 filed on Oct. 5, 2023 in the Korean Intellectual Property Office, the disclosure of which is incorporated herein by reference in its entirety.

### BACKGROUND

Inventive concepts relate to a semiconductor package.

Recently, high reliability of a semiconductor package installed in an electronic device has been sought after. Accordingly, research is being conducted into an arrangement of connection bumps located in a lower portion of the semiconductor package.

### SUMMARY

Example embodiments of inventive concepts relate to a semiconductor package having improved reliability.

According to example embodiments of inventive concepts, a semiconductor package includes a base substrate including a lower surface; a semiconductor chip on the base substrate; and a plurality of connection bumps on the lower surface of the base substrate, wherein the plurality of connection bumps includes a first group including connection bumps arranged on the lower surface in a first direction, and a second group including connection bumps arranged in a second direction having a first angle with respect to the first direction, the connection bumps of the first group are offset from each other in the first direction, and the connection bumps of the second group are offset from each other in the second direction.

According to example embodiments of inventive concepts, a semiconductor package includes a base substrate including a lower surface; a plurality of pads on the lower surface; a semiconductor chip disposed on the base substrate; a passivation layer on the lower surface of the base substrate and defining a plurality of openings, the plurality of openings exposing at least a portion of a surface of each of the plurality of lower pads; and a plurality of connection bumps in the plurality of openings, wherein the plurality of openings includes a first group including openings arranged on the lower surface in a first direction on the lower surface, and a second group including openings arranged on the lower surface in a second direction having a first angle with respect to the first direction, the openings of the first group are offset from each other in the first direction, and the openings of the second group are offset from each other in the second direction.

According to example embodiments of inventive concepts, a semiconductor package includes a base substrate; a semiconductor chip on the base substrate; and a plurality of connection bump units below the base substrate, wherein each of the plurality of connection bump units includes a plurality of connection bumps respectively located at a plurality of grid points, the plurality of grid points is arranged symmetrically with respect to a center point, and centers of at least a portion of the plurality of connection bumps are spaced apart from the plurality of grid points.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1 is a schematic cross-sectional view of a semiconductor package according to an example embodiment.

FIG. 2 is a schematic plan view of a semiconductor package according to an example embodiment.

FIG. 3 is a schematic partially enlarged view of a semiconductor package according to example embodiments.

FIG. 4 is a schematic partially enlarged view of a semiconductor package according to example embodiments.

FIG. 5 is a partially enlarged view illustrating a semiconductor package according to example embodiments.

FIG. 6 is a partially enlarged view illustrating a semiconductor package according to example embodiments.

FIGS. 7A to 12B are schematic cross-sectional views and plan views illustrating a method of manufacturing semiconductor packages according to example embodiments.

### DETAILED DESCRIPTION

Hereinafter, example embodiments will be described with reference to the attached drawings. Unless otherwise specified, in this specification, terms such as ‘on,’ ‘upper portion,’ ‘upper surface,’ ‘below,’ ‘lower portion,’ ‘lower surface,’ ‘side surface,’ and the like may be based on the drawings, and may be actually changed depending on a direction in which a component is disposed.

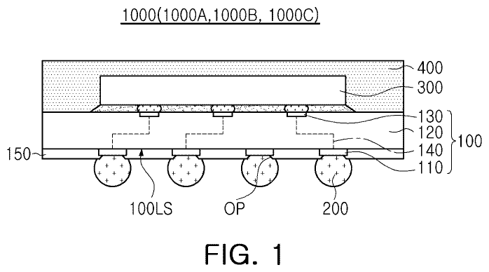

FIG. 1 is a schematic cross-sectional view of a semiconductor package 1000 according to an example embodiment.

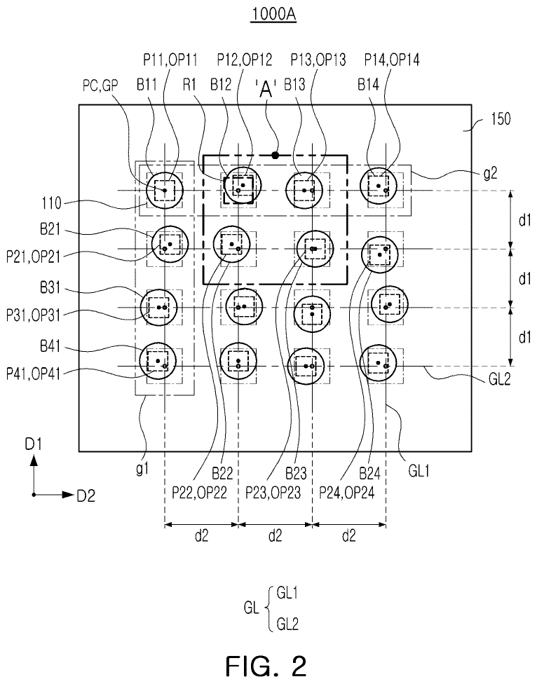

FIG. 2 is a schematic plan view of a semiconductor package 1000A according to an example embodiment.

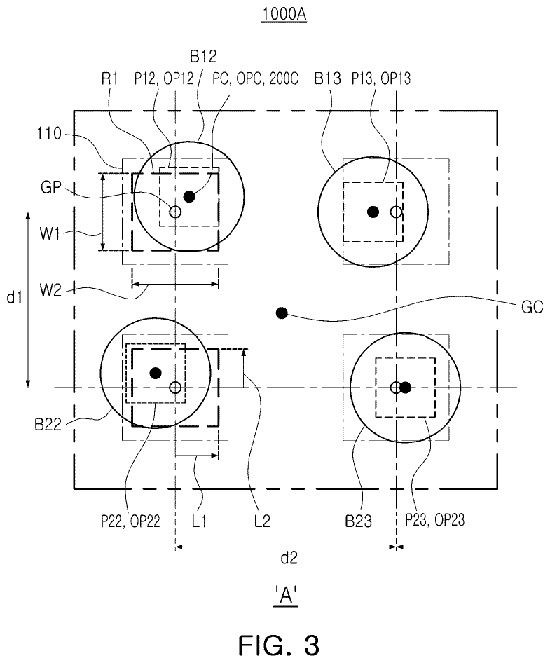

FIG. 3 is a schematic partially enlarged view of a semiconductor package 1000A according to example embodiments.

Referring to FIG. 1, a semiconductor package 1000 of an example embodiment may include a base substrate 100, a semiconductor chip 300 disposed on the base substrate 100, connection bumps 200 disposed below the base substrate 100, and an encapsulant 400 on the base substrate 100 and covering the semiconductor chip 300. According to an example embodiment, the connection bumps 200 may be disposed on virtual grid points GP arranged on a lower surface 100LS of the base substrate in a first direction (e.g., D1 direction) and in a second direction (e.g., D2 direction), the second direction perpendicular to the first direction (see FIG. 2).

According to an example embodiment, the connection bumps 200 may be arranged at a predetermined or, alternatively, a desired distance from the virtual grid points GP, and may be offset from each other, such that the unnecessary removal of connection bumps 200 may be reduced or prevented during a process of debonding a carrier film C surrounding the connection bumps 200 on the lower surface 100LS of the base substrate. Accordingly, when debonding the carrier film C, mechanical stress applied to the base substrate 100 may be distributed or reduced to reduce or prevent a phenomenon of occurring cracks or breaks in the base substrate 100, to provide the semiconductor package 1000 having improved reliability.

Hereinafter, each component will be described in detail with reference to the drawings.

The semiconductor chip 300 may include, for example, memory chips or memory elements that store or output data based on an address command, a control command, or the like received from the base substrate 100. For example, the semiconductor chip 300 may include, for example, a logic chip (or ‘a logic circuit’) such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC), or the like, a memory chip (or ‘a memory circuit’) including a volatile memory such as a dynamic RAM (DRAM), a static RAM (SRAM), or the like, a non-volatile memory such as a phase change RAM (PRAM), a magnetic RAM (MRAM), a resistive RAM (RRAM), a flash memory, or the like, but example embodiments are not limited thereto. The semiconductor chip 300 may have an inactive surface and an active surface opposite to the inactive surface, and may be disposed on the base substrate 100. In an example embodiment, the semiconductor chip 300 may be disposed in a flip chip manner such that the active surface of the semiconductor chip 300 faces an upper surface of the base substrate 100, but example embodiments are not limited thereto. For example, the semiconductor chip 300 may be disposed such that the inactive surface of the semiconductor chip 300 faces the upper surface of the base substrate 100 (not illustrated).

When the semiconductor chip 300 is disposed in a flip chip manner, an underfill layer surrounding bump structures disposed between the base substrate 100 and the semiconductor chip 300 and fixing the semiconductor chip 300 onto the base substrate 100 may be additionally disposed. The underfill layer may include, for example, an insulating material. The underfill layer may be formed using a CUF process, but example embodiments are not limited thereto. Additionally, although not illustrated, the semiconductor chip 300 may be attached to the upper surface of the base substrate 100 using an adhesive film (e.g., die attach film) attached to the inactive surface of the semiconductor chip 300. For example, the semiconductor chip 300 may be electrically connected to the base substrate 100 through conductive pads disposed on the active surface of the semiconductor chip 300 and conductive wires connected to upper pads 130 of the base substrate 100 (not illustrated).

The base substrate 100 may include an insulating layer 120, lower pads 110 disposed in a lower portion thereof, upper pads 130 disposed in an upper portion thereof, and a wiring circuit 140 electrically connecting the lower pads 110 and the upper pads 130. Accordingly, the base substrate 100 may transmit a signal or signals from the semiconductor chip 300 disposed thereon to the outside, and may also transmit a signal or signals and/or power from the outside to the semiconductor chip 300. The base substrate 100 may be, for example, a substrate for a semiconductor package including a printed circuit board (PCB), a ceramic substrate, a glass substrate, a tape wiring substrate, or the like, but example embodiments are not limited thereto. For example, the base substrate 100 may be a double-sided printed circuit board (PCB) or a multi-layer printed circuit board (multi-layer PCB).

The insulating layer 120 may include, for example, an insulating resin. The insulating resin may include, for example, a thermosetting resin such as an epoxy resin, a thermoplastic resin such as polyimide, or a resin impregnated with an inorganic filler or the like, such as a prepreg, an Ajinomoto build-up film (ABF), FR-4, bismaleimide-triazine (BT), but example embodiments are not limited thereto. For example, the insulating layer 120 may include a photosensitive resin such as a photoimageable dielectric (PID). The insulating layer 120 may include, for example, a plurality of insulating layers (not illustrated) stacked in a vertical direction. Depending on process, a boundary between the plurality of insulating layers (not illustrated) may be clear or unclear.

The lower pads 110 and the upper pads 130 may include, for example, at least one metal or at least one an alloy composed of two or more metals including, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), but example embodiments are not limited thereto.

A passivation layer 150 defining openings OP exposing at least a portion of a surface of each of the lower pads 110 may be disposed on the lower surface 100LS of the base substrate. The passivation layer 150 may, for example, include a solder resist containing, for example. an epoxy resin or a polyurethane resin, but example embodiments are not limited thereto. For example, the passivation layer 150 may include, for example, a photosensitive solder resist (PSR) containing a photosensitive resin composition. The passivation layer 150 may be formed using, for example, a screen-printing method, a roll coating technique, a curtain cotton technique, and a spraying technique, but example embodiments are not limited thereto. For example, when the solder resist is or includes a dry film, the passivation layer 150 may be formed using, for example, a film lamination technique. A surface of each of the lower pads 110 exposed by the openings OP may be referred to as open surfaces P.

Referring to FIGS. 2 and 3, to describe in more detail arrangement of the lower pads 110, the openings OP, and the open surfaces P exposed by the openings OP on the lower surface 100LS of the base substrate, virtual grid lines GL and virtual grids formed by crossing the virtual grid lines GL may be defined to be on the lower surface 100LS of the base substrate.

For example, the lower surface 100LS of the base substrate may have first virtual grid lines GL1 (or ‘first grid lines GL1’) extending in a first direction (D1 direction) and spaced apart by a second pitch d2 in a second direction (D2 direction), perpendicular to the first direction, may have second virtual grid lines GL2 (or ‘second grid lines GL2’) extending in the second direction (D2 direction) and spaced apart by the second pitch d2 in the first direction (D1 direction), and may have virtual grids (or ‘grids’) formed by crossing the first virtual grid lines GL1 and the second virtual grid lines GL2. Each of the virtual grids may have virtual center points GC (or ‘center points GC’), and may include virtual grid points GP (or ‘grid points GP’) surrounding a virtual center point GC. The virtual grid points GP may be arranged to be spaced apart by a first pitch d1 in the first direction (D1 direction), and may be arranged to be spaced apart by the second pitch d2 in the second direction (D2 direction).

To describe in more detail arrangement of the lower pads 110, the openings OP, and the open surfaces P exposed by the openings OP on the lower surface 100LS of the base substrate, the terms a first group g1 and a second group g2 may be used. The first group g1 may refer to openings, open surfaces, and connection bumps, arranged in a same column on the lower surface 100LS of the base substrate, respectively. For example, the first opening group may be a set of openings arranged in first, second, third, and fourth rows within a same column, respectively, a first open surface group may be a set of open surfaces arranged in first, second, third, and fourth rows within a same column, respectively, and a first connection bump group may be a set of connection bumps arranged in first, second, third, and fourth rows within a same column, respectively. Similarly, the second group g2 may refer to openings, open surfaces, and connection bumps, arranged in a same row on the lower surface 100LS of the base substrate.

The lower pads 110 may be arranged in rows and columns on the lower surface 100LS of the base substrate. For example, the lower pads 110 may be arranged on the lower surface 100LS of the base substrate, to be spaced apart by the first pitch dl in the first direction (D1 direction) and be spaced apart by the second pitch d2 in the second direction (D2 direction). A center of each of the lower pads 110 may be located to respectively overlap a grid point GP.

The openings OP may be arranged in rows and columns on the lower surface 100LS of the base substrate, a center OPC of each of the openings may be spaced apart from a corresponding grid point GP within a predetermined or, alternatively a desired range, and centers OPC of the openings may be located to be offset from each other in a predetermined or, alternatively a desired direction.

The openings OP may include first opening groups arranged in the first direction (D1 direction), and second opening groups arranged in the second direction (D2 direction), on the lower surface 100LS of the base substrate.

At least a portion of the centers OPC of individual openings included in each of the first and second opening groups may be spaced apart from corresponding grid points GP within a first range R1. For example, in a group located in a first row, among the second opening groups, a center OPC of an opening OP11 disposed in a first column may be located to overlap the grid point GP, and centers OPC of openings OP12, OP13, and OP14 arranged in second, third, and fourth columns may be located within the first range R1 away from respective grid points GP, but example embodiments are not limited thereto. For example, in a group located in a second row, among the second opening groups, centers of openings OP21, OP22, OP23, and OP24 arranged in first, second, third, and fourth columns may be located to be away from respective grid points GP within the first range R1.

The first range R1 may be a range in which a center OPC of openings is spaced apart from the grid points GP. The first range R1 may be centered on the grid point GP, and may have, for example, a first direction width W1 (or ‘vertical width W1’) of about 0.3 or less times the first pitch d1 in the first direction (D1 direction), for example, about 0.01 times to 0.3 times, 0.02 times to 0.3 times, 0.1 times to 0.3 times, 0.15 times to 0.3 times, or 0.2 times to 0.3 times the first pitch d1 in the first direction (D1 direction). In addition, the first range R1 may have a second direction width W2 (or ‘horizontal width W2’) of about 0.3 or less times the second pitch d2 in the second direction (D2 direction), for example, about 0.01 times to 0.3 times, 0.02 times to 0.3 times, 0.1 times to 0.3 times, 0.15 times to 0.3 times, or 0.2 times to 0.3 times the second pitch d2 in the second direction (D2 direction). In plan view, the openings OP may be located within the first range R1, and may be located such that a perimeter of each of the openings OP overlaps a respective grid point GP.

The center OPC of each of the openings may be defined as being spaced apart from a respective grid line GL at a predetermined or, alternatively a desired distance. For example, in the openings OP, the center OPC thereof may be spaced apart from the first grid line GL1 by a first distance L1, may be spaced apart from the second grid line GL2 by a second distance L2, or may be spaced apart from the first grid line GL1 by the first distance L1 and from the second grid line GL2 by the second distance L2.

The first distance L1 may be about 0.15 or less times the second pitch d2, for example, about 0.005 times to 0.15 times, 0.01 times to 0.15 times, 0.05 times to 0.15 times, 0.075 times to 0.15 times, or 0.1 times to 0.15 times the second pitch d2, and the second distance L2 may be, for example, about 0.15 or less times the first pitch d1, for example, about 0.005 times to 0.15 times, 0.01 times to 0.15 times, 0.05 times to 0.15 times, 0.075 times to 0.15 times, or 0.1 times to 0.15 times the first pitch d1.

As individual centers OPC of at least a portion of the openings may be located away from corresponding grid points GP or the grid lines GL, the openings OP may be offset in a predetermined or, alternatively a desired direction. For example, the openings (e.g., OP11, OP21, OP31, and OP41) included in the first opening groups may be offset from each other in the first direction (D1 direction), and the openings (e.g., OP11, OP12, OP13, and OP14) included in the second opening group may be offset from each other in the second direction (direction D2).

An open surface P of the open surfaces P may be a surface of a lower pad 110 at least a portion of which is exposed by an opening OP. The open surfaces P may be arranged in rows and columns on the lower surface 100LS of the base substrate, and a center PC of each of the open surfaces may vertically overlap a center OPC of an opening corresponding thereto. Accordingly, the center PC of each of the open surfaces may also be spaced apart from the grid point GP within a predetermined or, alternatively a desired range, and the centers PC of the open surfaces may be located to be offset from each other based on a predetermined or, alternatively a desired direction.

The open surfaces P may include first open surface groups arranged in the first direction (D1 direction), and second open surface groups arranged in the second direction (D2 direction), on the lower surface 100LS of the base substrate.

At least a portion of the centers PC of the open surfaces included in each of the first open surface groups and the second open surface groups may be spaced apart from respective grid points GP within the first range R1. For example, in a group located in the first row, among the second open surface groups, a center PC of an open surface P11 disposed in the first column may be located to overlap the grid point GP, and centers PC of open surfaces P12, P13, and P14 arranged in the second, third, and fourth rows may be located within the first range R1 away from respective grid points GP, but example embodiments are not limited thereto. For example, in a group located in the second row, among the second open surface groups, centers of open surfaces P21, P22, P23, and P24 arranged in the first, second, third, and fourth columns may be located to be away from the grid point GP and within the first range R1. The first range R1 in which the center PC of the open surfaces is spaced from the grid point GP may be the same as or substantially the same as a range in which the center OPC of the openings described above is spaced from the grid point GP.

The center PC of each of the open surfaces may be defined as being spaced apart from the grid line GL at a predetermined or, alternatively a desired distance. For example, in the open surfaces P, the center PC thereof may be spaced apart from the first grid line GL1 by the first distance L1, may be spaced apart from the second grid line GL2 by the second distance L2, or may be spaced apart from the first grid line GL1 by the first distance L1 and from the second grid line GL2 by the second distance L2. Each of the first distance L1 and the second distance L2 may be the same as or substantially the same as a distance by which the centers OPC of the openings described above are separated from the first grid line GL1 and the second grid line GL2, respectively.

As individual centers PC of at least a portion of the open surfaces may be located away from respective grid points GP or grid lines GL, the open surfaces P may be offset from each other in a predetermined or, alternatively, a desired direction. For example, the open surfaces (e.g., P11, P21, P31, and P41) included in the first open surface groups may be offset from each other in the first direction (D1 direction), and the open surfaces (e.g., P11, P12, P13, and P14) included in the second open surface groups may be offset from each other in the second direction (D2 direction).

The connection bumps 200 may be disposed below the base substrate 100 and/or below passivation layer 150. The connection bumps 200 may include, for example, tin (Sn), indium (In), bismuth (Bi), antimony (Sb), copper (Cu), silver (Ag), zinc (Zn), lead (Pb) and/or any alloy thereof, but example embodiments are not limited thereto. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like, but example embodiments are not limited thereto.

The connection bumps 200 may be arranged to contact the open surfaces P of the lower pads within the openings OP. Therefore, the connection bumps 200 may be arranged in rows and columns on the open surface P (and/or on the passivation layer 150), and a center 200C of each of the connection bumps may vertically overlap center OPC of openings and center PC of open surfaces, corresponding thereto. Accordingly, the center 200C of each of the connection bumps may also be spaced apart from respective grid points GP within a predetermined or, alternatively, a desired range, and centers 200C of the connection bumps may be located to be individually offset from each other based on a predetermined or, alternatively, a desired direction.

The connection bumps 200 may include first connection bump groups arranged in the first direction (D1 direction), and second connection bump groups arranged in the second direction (D2 direction), on the lower surface 100LS of the base substrate and/or the passivation layer 150.

At least a portion of the centers 200C of the connection bumps included in each of the first and second connection bump groups may be spaced apart from respective grid points GP within the first range R1. For example, in a group located in the first row, among the second connection bump groups, a center 200C of a connection bump B11 disposed in the first column may be located to overlap the grid point GP, and similarly centers 200C of connection bumps B12, B13, and B14 arranged in the second, third, and fourth rows may be located within the first range R1 away from respective grid points GP, but example embodiments are not limited thereto. For example, in a group located in the second row, among the second connection bump groups, centers of connection bumps B21, B22, B23, and B24 arranged in the first, second, third, and fourth columns may be located to be away from respective grid point GP and within the first range R1. The first range R1 in which centers of the connection bumps are spaced apart from respective grid points GP may be the same as or substantially the same as a range in which centers OPC of the openings (or ‘centers PC of open surfaces’) described above are spaced apart from respective grid points GP.

The center 200C of each of the connection bumps may be defined as being spaced apart from respective grid lines GL at a predetermined or, alternatively, a desired distance. For example, regarding the connection bumps 200, a center 200C thereof may be spaced apart from a first grid line GL1 by a first distance L1, may be spaced apart from the second grid line GL2 by a second distance L2, or may be spaced apart from the first grid line GL1 by the first distance L1 and from the second grid line GL2 by the second distance L2. Each of the first distance L1 and the second distance L2 may be the same as or substantially the same as a distance by which the centers OPC of the openings (or ‘center PC of the open surfaces’) described above are separated from the first grid line GL1 and the second grid line GL2, respectively.

As centers 200C of at least a portion of the connection bumps are located away from the grid points GP or the grid lines GL, the connection bumps 200 may be offset from each other in a predetermined or, alternatively, a desired direction. For example, the connection bumps (e.g., B11, B21, B31, and B41) included in the first connection bump groups may be offset from each other in the first direction (D1 direction), and the connection bumps (e.g., B11, B12, B13, and B14) included in the second connection bump groups may be offset from each other in the second direction (D2 direction).

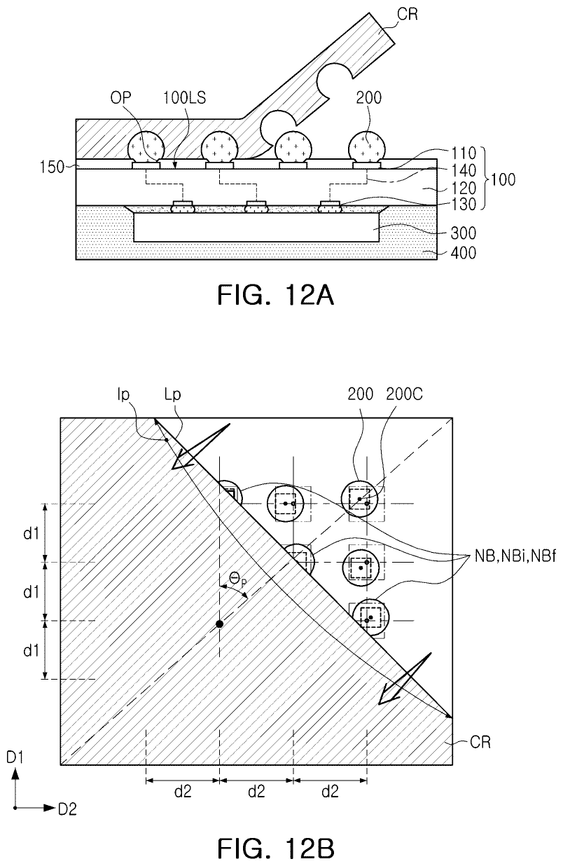

According to an example embodiment, centers of individual connection bumps 200 may be located at a predetermined or, alternatively, a desired distance from a corresponding grid point GP, and the connection bumps 200 may be arranged to be offset from each other in the first direction (D1 direction) and may be arranged to be offset from each other in the second direction (D2 direction), to have an effect of reducing or preventing unnecessary removal of the connection bumps 200 during a process of debonding a carrier CR surrounding the connection bumps 200 on a lower surface 100LS (or ‘passivation layer 150’) of a base substrate (see FIGS. 12A and 12B).

The effect may be measured by a density (D) of the connection bumps on a peeling line Lp, and a change rate (ΔD) thereof.

The density (D) of the connection bumps may be defined as a ratio of the number (NB) of connection bumps existing on the peeling line Lp, relative to a length (lp) of the peeling line Lp formed on an upper surface of a passivation layer 150 when the carrier CR is debonded, as illustrated below.

Density (D)=(Number (NB) of Connection Bumps present on Peeling Line)/(Length (lp) of Peeling Line)

The density change rate (ΔD) of the connection bumps may be defined as the number (NBf) of connection bumps remaining on the peeling line Lp after debonding of the carrier CR relative to the number (NBi) of connection bumps existing on the peeling line Lp before debonding of the carrier CR.

Density Change Rate (ΔD)=(Number (NBf) of Connection Bumps remaining on Peeling Line after debonding of Carrier)/(Number (Nbi) of Connection Bumps remaining on Peeling Line before debonding of Carrier)

According to an example embodiment, compared to a case in which centers of connection bumps 200 is disposed to overlap corresponding grid points GP, a density change rate ΔD of the connection bumps may be reduced. For example, according to an example embodiment, centers of connection bumps 200 may be located to be spaced apart from corresponding grid points GP, and the connection bumps 200 may be arranged to be offset from each other in the first direction (D1 direction) and the second direction (D2 direction), to reduce or prevent unnecessary removal of connection bumps existing on the peeling line Lp along with a carrier CR to be debonded. Therefore, when debonding the carrier CR, a mechanical stress applied to a base substrate 100 may be distributed or reduced to reduce or prevent a phenomenon of cracks or breaks occurring in the base substrate 100, to provide a semiconductor package 1000A having improved reliability.

The encapsulant 400 covering the semiconductor chip 300 may be disposed on the base substrate 100. The encapsulant 400 may protect the semiconductor chip 300 from external environments such as, for example, a physical shock, moisture, or the like. The encapsulant 400 may be formed, for example, by curing an epoxy molding compound (EMC), but example embodiments are not limited thereto.

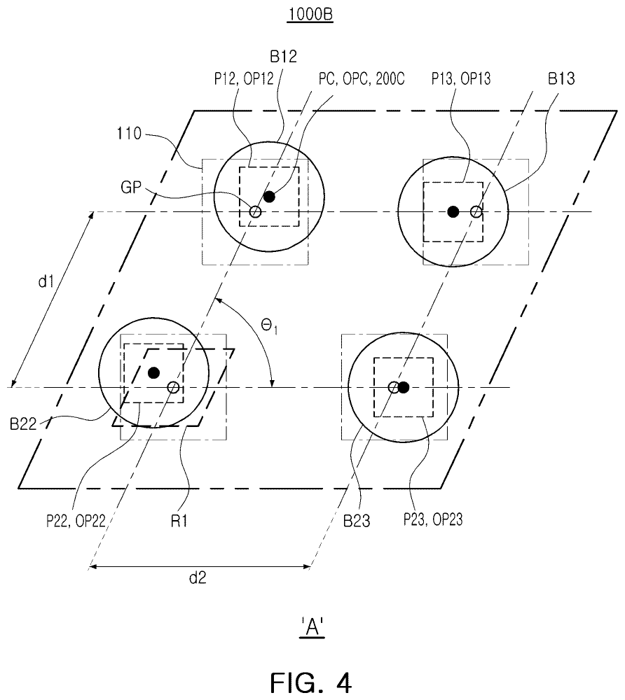

FIG. 4 is a plan view illustrating a semiconductor package 1000B according to example embodiments.

Referring to FIG. 4, openings OP, open surfaces P, and connection bumps 200 may be arranged in a first direction (D1 direction) and a second direction (D2 direction). A configuration in which the above components are arranged may be the same as those described with reference to FIGS. 1 to 3, except that a first angle θ1 formed by the second direction (D2 direction) and the first direction (D1 direction) is an acute angle.

Referring to FIG. 4, a first range R1 may be centered on a grid point GP, may have a first direction width W1 in the first direction (D1 direction), and may have a second direction width W2 in the second direction (D2 direction) having an acute angle with respect to the first direction (D1 direction). Therefore, the first range R1 may have a rhombus or rhomboid shape in plan view.

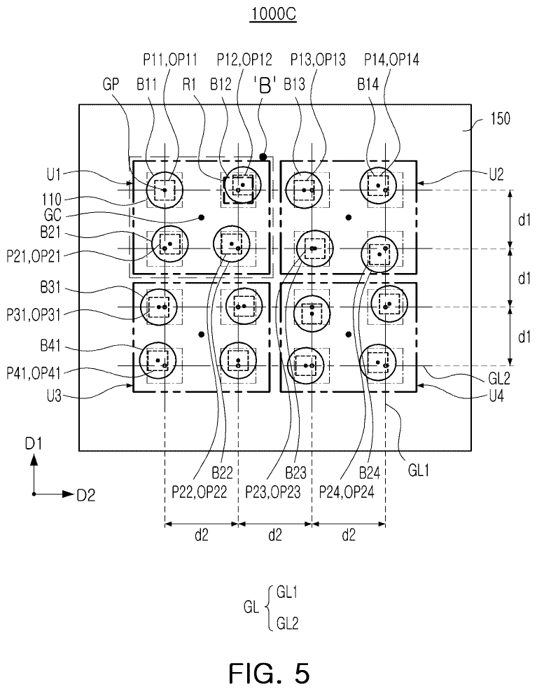

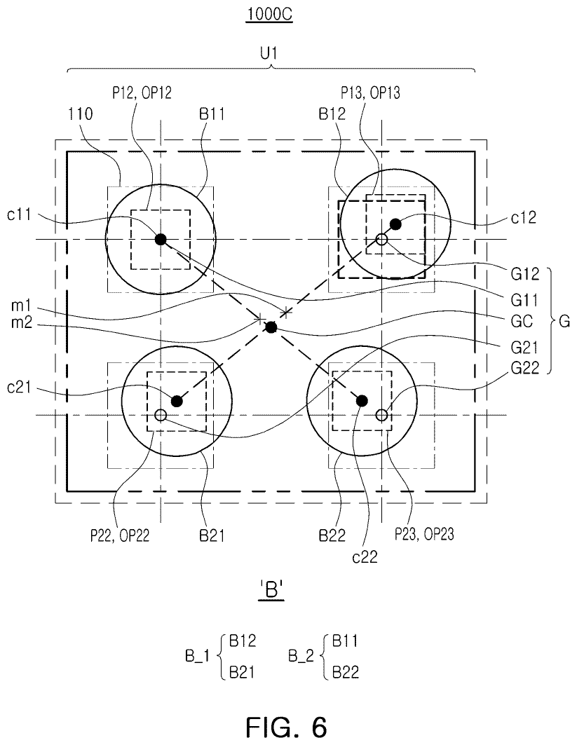

FIG. 5 is a partially enlarged view illustrating a semiconductor package 1000C according to example embodiments. FIG. 6 is a partially enlarged view illustrating a semiconductor package 1000C according to example embodiments.

Referring to FIG. 5, a configuration thereof may be the same as those described with reference to FIGS. 1 to 3, except that connection bumps may be defined as a plurality of units U1, U2, U3, and U4 (or ‘connection bump units’) and disposed below a base substrate.

Referring to FIG. 5, each of the plurality of units U1, U2, U3, and U4 may include a plurality of connection bumps respectively disposed at grid points GP surrounding an arbitrary center point GC.

Referring to FIGS. 5 and 6 together, a connection bump unit U1 disposed on an upper left side of a lower surface LS of a base substrate may include first connection bumps B12 and B21 (or first connection bumps “B_1”) respectively disposed at first grid points G12 and G21 facing each other in a diagonal direction, and second connection bumps B11 and B22 (or second connection bumps “B_2”) respectively disposed at second grid points G11 and G22 facing each other in a different diagonal direction. For example, at least one of the first connection bumps B_1 or the second connection bumps B_2 may not be symmetrical with respect to center point GC.

For example, a first midpoint m1 located on a first virtual connection line connecting centers c12 and c21 of each of the first connection bumps B12 and B21 and at the same distance from the centers c12 and c21 may be spaced apart from the center point GC, and/or a second midpoint m2 located on a second virtual connection line connecting centers c11 and c22 of each of the second connection bumps B11 and B22 and at the same distance from the centers c11 and c22 may be spaced apart from the central point GC. Referring to FIGS. 5 and 6 together, at least one of the centers c12 and c21 of the first connection bumps B_1 or the centers c11 and c22 of the second connection bumps B_2 may be arranged not symmetrically relative to the center point GC, in order to distribute or reduce a mechanical stress applied to a base substrate 100 when debonding a carrier film C. Accordingly, a phenomenon of cracks or breaks occurring in the base substrate 100 may be reduced or prevented to provide a semiconductor package having improved reliability.

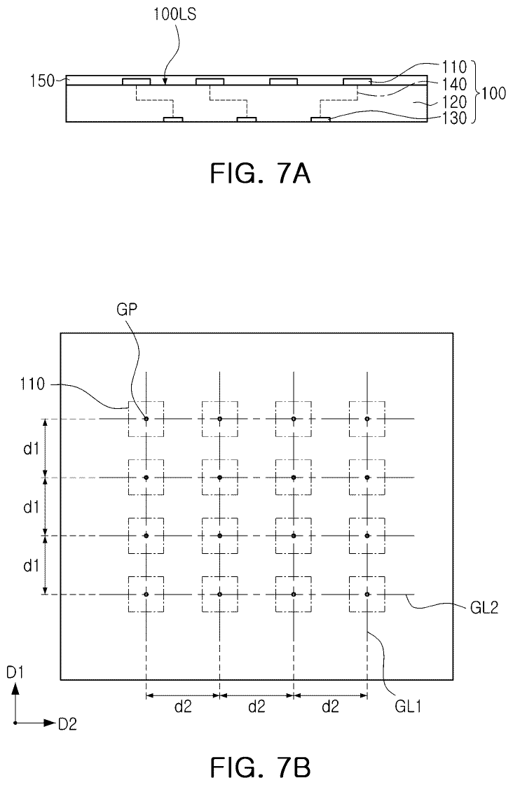

FIGS. 7A to 12B are schematic cross-sectional views and plan views illustrating a method of manufacturing semiconductor packages 1000 and 1000A according to example embodiments.

Specifically, FIGS. 7A, 8A, 9A, 10A, 11A, and 12A are schematic cross-sectional views illustrating a method of manufacturing semiconductor packages 1000 and 1000A according to example embodiments, and FIGS. 7B, 8B, 9B, 10B, 11B, and 12B are schematic plan views illustrating a method of manufacturing semiconductor packages 1000 and 1000A according to example embodiments.

Referring to FIG. 7A, a preliminary package including a base substrate 100 and a passivation layer 150 disposed on a lower surface 100LS of the base substrate may be provided to have a face-up state.

Referring to FIG. 7B, first grid lines GL1 may be defined as extending in a first direction (D1 direction) on the lower surface 100LS of the base substrate and being spaced apart by a second pitch d2 in a second direction (D2 direction), perpendicular to the first direction, second grid lines GL2 may be defined as extending in the second direction (D2 direction) and spaced apart by a first pitch d1 in the first direction (D1 direction), and grid points GP may be defined as being formed by crossing the first grid lines GL1 and the second grid lines GL2.

A center of each lower pad 110 may be formed to overlap grid points GP corresponding thereto. For example, the lower pads 110 may be formed on the lower surface 100LS of the base substrate, such that centers of adjacent lower pads are spaced apart from each other by a first pitch dl in the first direction (D1 direction) and by a second pitch d2 in the second direction (D2 direction).

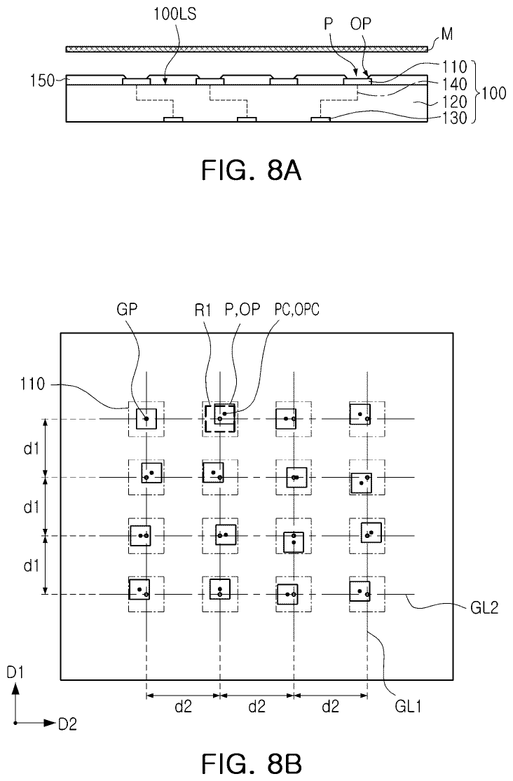

Referring to FIG. 8A, a patterned photo mask M may be aligned on the preliminary package, and openings OP exposing at least a portion of a surface P (or ‘open surface P’) of each of the lower pads 110 may be formed by, for example, a lithography process.

Referring to FIG. 8B, the openings OP may be formed such that a center OPC of each of the openings may be located within a predetermined or, alternatively, a desired range from a grid point GP. Referring to FIGS. 2 and 3 together, the center OPC of the opening may be formed to be located within a first range R1 from the grid point GP. The openings OP may be formed to be offset from each other in the first direction (D1 direction) and the second direction (D2 direction).

A center PC of the open surface may be formed to overlap a corresponding center OPC of the openings. Referring to FIGS. 2 and 3 together, the center PC of the open surface may be formed to be located within the first range R1 from the grid point GP. The open surfaces P may be formed to be offset from each other in the first direction (D1 direction) and the second direction (D2 direction).

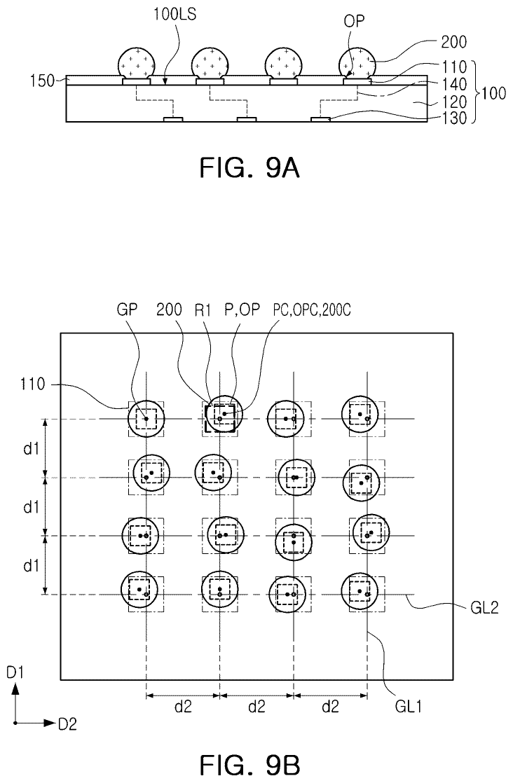

Referring to FIG. 9A, connection bumps 200 contacting the open surface P may be formed in the openings OP.

Referring to FIG. 9B, a center 200C of the connection bumps may be formed to overlap the center PC of the open surface and the center OPC of the openings. Referring to FIGS. 2 and 3 together, the centers 200C of the connection bumps may be formed to be located within the first range R1 from the grid point GP. The connection bumps 200 may be formed to be offset from each other in the first direction (D1 direction) and the second direction (D2 direction).

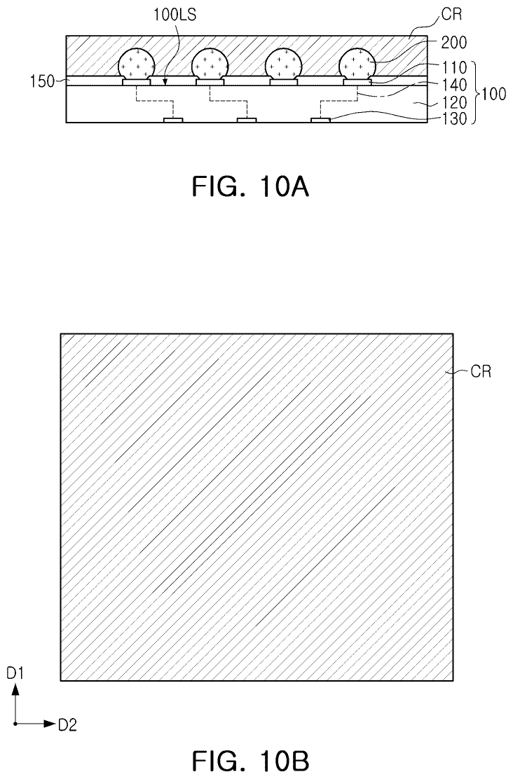

Referring to FIGS. 10A and 10B, a carrier CR surrounding the connection bumps 200 may be formed on the passivation layer 150.

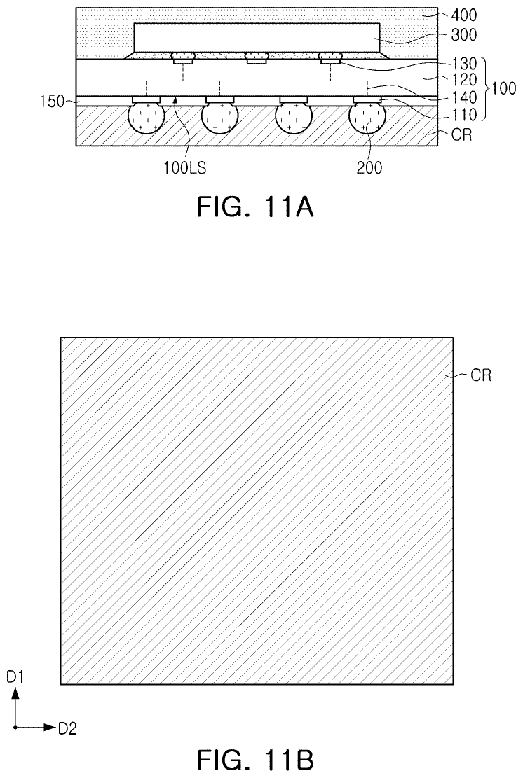

For a side process of a back semiconductor chip 300 of FIGS. 11A and 11B, a predetermined or, alternatively, a desired temporary adhesive (not illustrated) may be applied on the passivation layer 150, and a carrier CR may be then formed.

Referring to FIG. 11A, a semiconductor chip 300 may be mounted on the base substrate 100, and a backside process may be performed to form an encapsulant 400 surrounding the semiconductor chip 300 on the base substrate 100.

The semiconductor chip 300 may be mounted on the base substrate 100 by bump structures attached to a lower surface of the semiconductor chip 300. The semiconductor chip 300 may be firmly fixed on the base substrate 100 by filling an underfill material between the attached bump structures.

Afterwards, the encapsulant 400 may be formed on the base substrate 100 to cover the semiconductor chip 300. The encapsulant 400 may seal a circumference of the semiconductor chip 300 to protect the same from external environments such as, for example, a physical shock, moisture, or the like.

Referring to FIG. 11B, when performing the backside process (FIG. 11A), the base substrate 100 may be firmly supported by the carrier CR formed according to FIG. 10.

Referring to FIG. 12A, the carrier CR on the passivation layer 150 may be debonded.

Referring to FIG. 12B, the carrier CR may be removed at a predetermined or, alternatively, a desired debonding angle θp with the base substrate 100. A range of the debonding angle θp may not be not particularly limited. For example, the debonding angle θp may range from 0° to 360°. When the carrier CR is debonded, the debonding angle θp at which a density change rate (ΔD) on a peeling line Lp of offset connection bumps 200 is reduced or minimized may be selected as a process condition of an example embodiment of inventive concepts.

When the carrier CR is debonded on the passivation layer 150, the peeling line Lp may be formed on the passivation layer 150. When debonding the carrier CR, the peeling line Lp may be formed in a direction perpendicular to a direction in which the carrier CR is debonded, in a boundary portion in which the carrier CR and the passivation layer 150 are in contact with each other. The peeling line Lp may have a first length lp, and a size of the first length lp is not particularly limited. For example, the first length lp may be determined in various manners depending on a size of the base substrate 100 or a range of the debonding angle θp. Additionally, the peeling line Lp may be, for example, continuously formed on the passivation layer 150 in the direction in which the carrier CR is debonded but example embodiments are not limited thereto.

According to an example embodiment, a center 200C of the connection bumps may be located to be spaced apart from a grid point GP, and the connection bumps 200 may be offset from each other in the first direction (D1 direction) and the second direction (D2 direction), to have an effect of reducing or preventing unnecessary removal of the connection bumps 200 during a process of debonding the carrier CR.

The aforementioned effect may be measured by a density (D) of the connection bumps on the peeling line Lp, and a change rate (ΔD) thereof.

As explained with reference to FIGS. 1 to 3, the density (D) of the connection bumps may be defined as a ratio of the number (NB) of connection bumps existing on the peeling line Lp, relative to a length (lp) of the peeling line formed when the carrier CR is debonded.

Density (D)=(Number (NB) of Connection Bumps present on Peeling Line)/(Length (lp) of Peeling Line)

The density change rate (ΔD) of the connection bumps may be defined as the number (NBf) of connection bumps remaining on the peeling line Lp after debonding of the carrier CR relative to the number (Nbi) of connection bumps existing on the peeling line Lp before debonding of the carrier CR.

Density Change Rate (ΔD)=(Number (NBf) of Connection Bumps remaining on Peeling Line after debonding of Carrier)/(Number (Nbi) of Connection Bumps remaining on Peeling Line before debonding of Carrier)

According to an example embodiment, compared to a case in which the center 200C of the connection bumps is disposed to overlap the grid point GP, the density change rate ΔD of the connection bumps may be reduced. For example, according to an example embodiment, in the process of debonding the carrier CR, unnecessary removal of the connection bumps existing on the peeling line Lp together with a temporary adhesive may be reduced or prevented (not illustrated). Accordingly, when debonding the carrier CR, a mechanical stress applied to the base substrate 100 may be distributed or reduced to reduce or prevent a phenomenon of occurring cracks or breaks in the base substrate 100, to provide a semiconductor package 1000A having improved reliability.

According to example embodiments, a semiconductor package having improved reliability may be provided.

Various advantages and effects of inventive concepts are not limited to the above-described content, and can be more easily understood through description of specific example embodiments.

While example embodiments have been illustrated and described above, it will be apparent to those ordinarily skilled in the art that modifications and variations could be made without departing from the spirit and scope of the inventive concepts as in the appended claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A semiconductor package comprising:
a base substrate including a lower surface;
a semiconductor chip on the base substrate; and
a plurality of connection bumps on the lower surface of the base substrate,
wherein the plurality of connection bumps includes a first group and a second group, the first group including connection bumps arranged on the lower surface in a first direction, and the second group including connection bumps arranged in a second direction, the second direction having a first angle with respect to the first direction,
the connection bumps of the first group are offset from each other in the first direction, and
the connection bumps of the second group are offset from each other in the second direction.

2. The semiconductor package of claim 1, wherein the lower surface of the base substrate comprises virtual grid points arranged to be apart from each other by a first pitch in the first direction and spaced apart from each other by a second pitch in the second direction, the second pitch being different from the first pitch
wherein centers of at least a portion of the plurality of connection bumps are spaced apart from the virtual grid points.

3. The semiconductor package of claim 2, wherein centers of the at least a portion of the plurality of connection bumps are located within a first range centered on virtual grid points corresponding thereto,
wherein the first range has a vertical width 0.3 or less times the first pitch in the first direction, and a horizontal width 0.3 or less times the second pitch in the second direction.

4. The semiconductor package of claim 2, wherein the plurality of connection bumps are arranged such that each of the virtual grid points is located within a circumference of corresponding ones of the plurality of connection bumps when viewed in plan view.

5. The semiconductor package of claim 1, wherein the lower surface of the base substrate comprises first grid lines extending in the first direction and spaced apart from each other by a second pitch in the second direction,
wherein at least a portion of centers of connection bumps, among the plurality of connection bumps, arranged in the first direction are spaced apart from the first grid lines in the second direction by 0.15 or less times the second pitch.

6. The semiconductor package of claim 1, wherein the lower surface of the base substrate comprises second grid lines extending in the second direction and spaced apart from each other by a first pitch in the first direction,
wherein at least a portion of centers of connection bumps, among the plurality of connection bumps, arranged in the second direction are spaced apart from the second grid lines in the first direction by 0.15 or less times the first pitch.

7. The semiconductor package of claim 1, wherein the lower surface of the base substrate comprises first grid lines and second grid lines, the first grid lines extending in the first direction and spaced apart from each other by a second pitch in the second direction, and the second grid lines extending in the second direction and spaced apart from each other by a first pitch in the first direction, the first pitch different from the second pitch,
wherein centers of at least a portion of the connection bumps of the first group are spaced apart from the first grid lines by a first distance in the second direction, and
centers of at least a portion of the connection bumps of the second group are spaced apart from the second grid lines by a second distance in the first direction,
wherein the first distance is 0.15 or less times the second pitch, and the second distance is 0.15 or less times the first pitch.

8. The semiconductor package of claim 1, wherein the base substrate further comprises lower pads,
and the plurality of connection bumps are on the lower pads.

9. The semiconductor package of claim 1, wherein the first angle is a right angle.

10. The semiconductor package of claim 1, wherein the first angle is an acute angle.

11. A semiconductor package comprising:
a base substrate including a lower surface;
a plurality of pads on the lower surface;
a semiconductor chip on the base substrate;
a passivation layer on the lower surface of the base substrate and defining a plurality of openings, the plurality of openings exposing at least a portion of a surface of each of the plurality of lower pads; and
a plurality of connection bumps in the plurality of openings,
wherein the plurality of openings includes a first group and a second group, the first group including openings arranged on the lower surface in a first direction, and the second group including openings arranged on the lower surface in a second direction, the second direction having a first angle with respect to the first direction,
the openings of the first group are offset from each other in the first direction, and
the openings of the second group are offset from each other in the second direction.

12. The semiconductor package of claim 11, wherein the lower surface of the base substrate comprises virtual grid points arranged spaced apart from each other by a first pitch in the first direction and spaced apart by a second pitch in the second direction, the second pitch different from the first pitch,
wherein centers of at least a portion of the plurality of openings are spaced apart from the virtual grid points.

13. The semiconductor package of claim 12, wherein the plurality of openings overlaps with the virtual grid points when viewed in plan view.

14. The semiconductor package of claim 12, wherein centers of each of the at least a portion of the plurality of openings are located within a first range centered on a virtual grid point corresponding thereto,
and the first range has a vertical width 0.3 or less times the first pitch in the first direction, and a horizontal width 0.3 or less times the second pitch in the second direction.

15. The semiconductor package of claim 11, wherein the plurality of lower pads with the exposed surfaces comprises a third group and a fourth group, the third group including lower pads arranged on the lower surface in the first direction, and the fourth group including lower pads arranged in the second direction,
the surfaces of the lower pads of the third group are offset from each other in the first direction, and
the surfaces of the lower pads of the fourth group are offset from each other in the second direction.

16. The semiconductor package of claim 15, wherein individual ones of the plurality of connection bumps are in contact with corresponding ones of the surfaces of the plurality of lower pads in the plurality of openings.

17. The semiconductor package of claim 16, wherein centers of the plurality of connection bumps are vertically aligned with centers of the plurality of lower pads.

18. A semiconductor package comprising:
a base substrate;
a semiconductor chip on the base substrate; and
a plurality of connection bump units below the base substrate,
wherein each of the plurality of connection bump units includes a plurality of connection bumps respectively located at a plurality of grid points,
the plurality of grid points are arranged symmetrically with respect to a center point, and
centers of at least a portion of the plurality of connection bumps are spaced apart from the plurality of grid points.

19. The semiconductor package of claim 18, wherein the centers of the at least a portion of the plurality of connection bumps are not symmetrically located with respect to the center point.

20. The semiconductor package of claim 18, wherein the plurality of connection bump units are arranged in a first direction and a second direction, the second direction having an angle with respect to the first direction.
